(19) United States
(12) Patent Application Publication
(10) Pub. No.: US 2026/0033213 A1
(43) Pub. Date: Jan. 29, 2026

(54) OLED DISPLAY DEVICE AND CURVED DISPLAY DEVICE THEREOF

(71) Applicant: AmTRAN TECHNOLOGY CO., LTD, New Taipel City (TW)

(72) Inventor: Kwang-Tao Chen, New Taipel City (TW)

(73) Assignee: AmTRAN TECHNOLOGY CO., LTD, New Taipei City (TW)

(21) Appl. No.: 19/309,637

(22) Filed: Aug. 26, 2025

Related U.S. Application Data
(63) Continuation-in-part of application No. 18/670,676, filed on May 21, 2024.
(60) Provisional application No. 63/741,455, filed on Jan. 3, 2025.

(30) Foreign Application Priority Data
Jan. 3, 2024 (TW) 113100285

(51) Int. Cl. H10K 59/80; H10K 59/95

(52) U.S. Cl. CPC H10K 59/872; H10K 59/95

(57) ABSTRACT

An OLED display device includes an OLED panel module, a flexible circuit board, a back plate, and first support adhesive tapes. The flexible circuit board is electrically connected from a bottom of the OLED panel module. The back plate extends to a top, the bottom, and two lateral sides of the OLED panel module to have a top wall, a bottom wall and two side walls respectively for surrounding the OLED panel module and the flexible circuit board. Support sheet portions are formed by extending and repeatedly bending at least two of the top wall, the bottom wall and the two side walls. The first adhesive tapes are attached between the support sheet portions and the OLED panel module, for supporting the OLED panel module cooperatively with the support sheet portions.

### CROSS REFERENCE TO RELATED APPLICATIONS

This application is a continuation-in-part of U.S. application Ser. No. 18/670,676, filed on May 21, 2024. Further, this application claims the benefit of U.S. Provisional Application No. 63/741,455, filed on Jan. 3, 2025. The contents of these applications are incorporated herein by reference.

### BACKGROUND OF THE INVENTION

### 1. Field of the Invention

The present invention relates to a display device, and more specifically, to an OLED display device utilizing a clamping slot portion bent from a back plate or a bracket for detachably fixing a covering sheet covering a flexible circuit board.

### 2. Description of the Prior Art

Due to the advantages of OLED (Organic Electro-Luminescent Display) panel modules, which are thinner and more energy-efficient and display more vibrant images than LCD (Liquid Crystal Display) panels, the OLED panel modules have been widely applied to display devices. Currently, during the assembly of OLED display devices, it is necessary to electrically connect the OLED panel modules to the main circuit boards behind the OLED panel modules via flexible circuits. Since folded portions of the flexible circuits require space for installation and cannot be exposed, the folded portions need to be covered by covering structures on the front surface of the OLED display devices, which prevent visibility of the folded portions from the front. The covering structures are usually external covering cases fixed to the middle frames or fasteners in the OLED display devices with screws or buckles. However, the aforesaid designs are prone to risks of manual misalignments during mass production, thereby leading to assembly defects. Moreover, the middle frames and the fasteners occupy internal space of the OLED display devices and require assembly steps during mass production, resulting in increased costs for OLED display devices.

Furthermore, the OLED display devices usually utilize inner metal plates for supporting the OLED panel modules via attachment of adhesive tapes between the inner metal plates and the OLED panel modules. However, the additional inner metal plates and adhesive tapes occupy internal space of the OLED display devices and require time-consuming and strenuous assembly steps during mass production, so as to increase manufacturing costs for the OLED display devices and be disadvantageous to the thinning designs of the OLED display devices.

### SUMMARY OF THE INVENTION

The present invention provides an OLED display device including an OLED panel module, at least one flexible circuit board, a back plate, and at least two first support adhesive tapes. The at least one flexible circuit board is electrically connected from a bottom of the OLED panel module. The back plate extends to a top, the bottom, and two lateral sides of the OLED panel module to have a top wall, a bottom wall and two side walls respectively for surrounding the OLED panel module and the at least one flexible circuit board. At least two support sheet portions are formed by extending and repeatedly bending at least two of the top wall, the bottom wall and the two side walls. The at least two first adhesive tapes are attached between the at least two support sheet portions and the OLED panel module, for supporting the OLED panel module cooperatively with the at least two support sheet portions.

The present invention further provides an OLED display device including an OLED panel module, a flexible circuit board, a back plate, and a covering sheet. The OLED panel module has a display area and a non-display area located on a front surface of the OLED panel module. The flexible circuit board is electrically connected and bent backward from a bottom of the OLED panel module to form at least one folded board portion attached to a back surface of the OLED panel module. The back plate extends to a top, the bottom, and two lateral sides of the OLED panel module to have a top wall, a bottom wall and two side walls respectively for surrounding the OLED panel module and the flexible circuit board, wherein at least two support sheet portions are formed by extending and repeatedly bending at least two of the top wall, the bottom wall and the two side walls. The bottom wall covers the OLED panel module and the flexible circuit board at the bottom, at least one clamping slot portion is formed by extending and repeatedly bending at least one portion of the bottom wall, at least one clamping slot space is formed between the at least one clamping slot portion and the back plate, and the back plate, the bottom wall and the at least one clamping slot portion are formed integrally in one piece. The covering sheet covers the flexible circuit board and the non-display area. The covering sheet has at least one hook portion and a covering portion. The at least one hook portion extends and bends from the covering portion, wherein the at least one hook portion is inserted into the at least one clamping slot space such that the clamping slot portion is between the at least one hook portion and the covering portion.

The present invention further provides a curved display device including a curved OLED panel module, at least one flexible circuit board, a back plate, and at least two first adhesive tapes. The at least one flexible circuit board is electrically connected from a bottom of the curved OLED panel module. The back plate extends to a top, the bottom, and two lateral sides of the curved OLED panel module to have a top wall, a bottom wall and two side walls respectively for surrounding the curved OLED panel module and the at least one flexible circuit board, wherein the top wall and the bottom wall of the back plate are curved along the top and the bottom of the curved OLED panel module respectively, and at least two support sheet portions are formed by extending and repeatedly bending at least two of the top wall, the bottom wall and the two side walls. The at least two first adhesive tapes are attached between the at least two support sheet portions and the curved OLED panel module, for supporting the curved OLED panel module cooperatively with the at least two support sheet portions.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view of an OLED display device according to an embodiment of the present invention.

FIG. 2 is a partial exploded view of the OLED display device in FIG. 1.

FIG. 3 is a back-side view of an OLED panel module in FIG. 2.

FIG. 4 is a back-side view of a covering sheet in FIG. 2.

FIG. 5 is a partial cross-sectional view of the OLED display device along a cross-sectional line A-A in FIG. 1.

FIG. 6 is an exploded view showing a back side of the OLED display device in FIG. 1.

FIG. 7 is a partial enlarged diagram of the OLED panel module mounted on a bracket.

FIG. 8 is a partial cross-sectional diagram of an OLED display device according to one embodiment of the present invention.

FIG. 9 is a partial exploded view of an OLED display device according to another embodiment of the present invention.

FIG. 10 is a partial exploded view of the OLED display device in FIG. 9 from another viewing angle.

FIG. 11 is a partial cross-sectional diagram of the OLED display device in FIG. 9 along a cross-sectional line C-C after assembly.

FIG. 12 is another partial cross-sectional diagram of the OLED display device in FIG. 9 along the cross-sectional line C-C after assembly.

FIG. 13 is a partial cross-sectional diagram of the OLED display device in FIG. 9 along a cross-sectional line D-D after assembly.

FIG. 14 is a partial enlarged diagram of a back plate supporting an OLED panel module according to another embodiment of the present invention.

### DETAILED DESCRIPTION

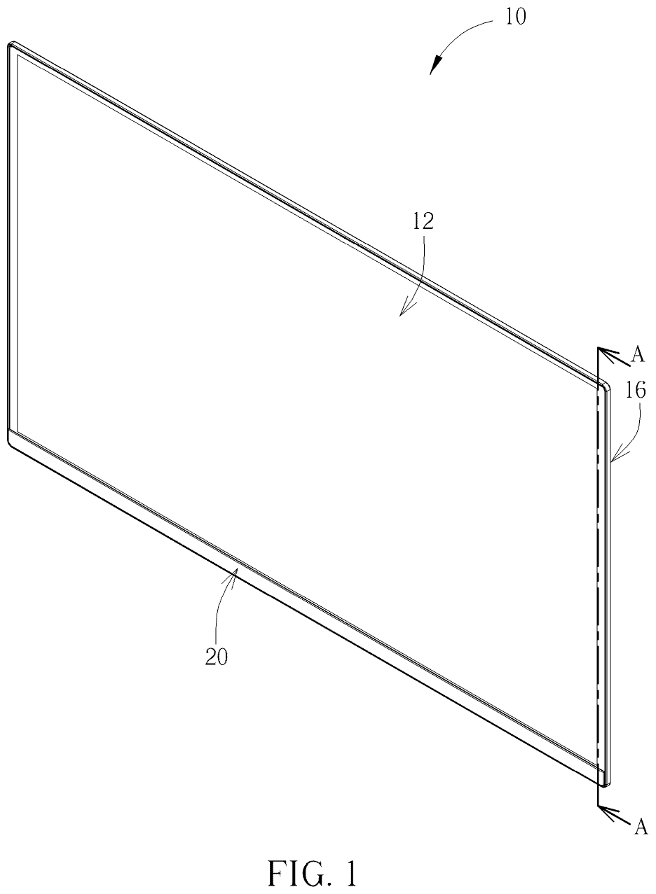

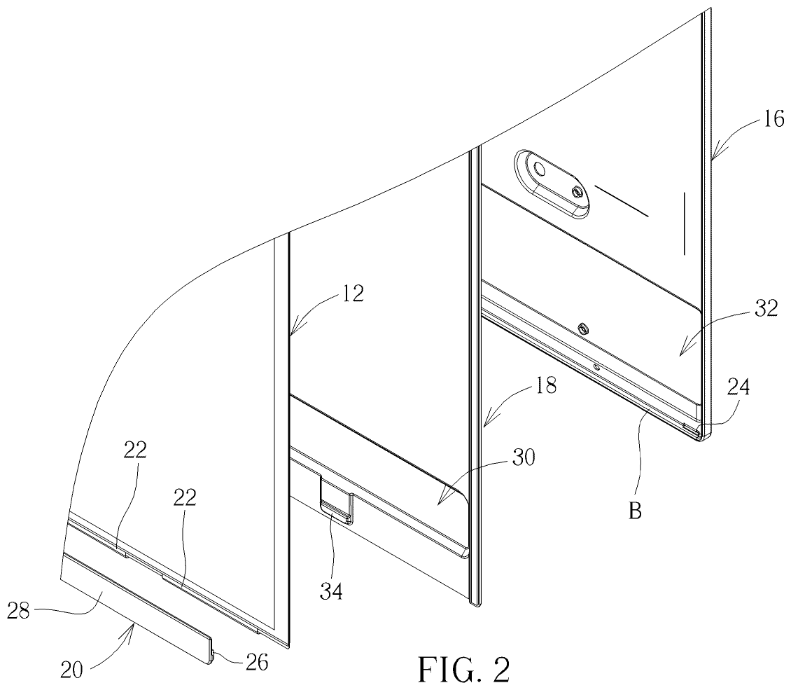

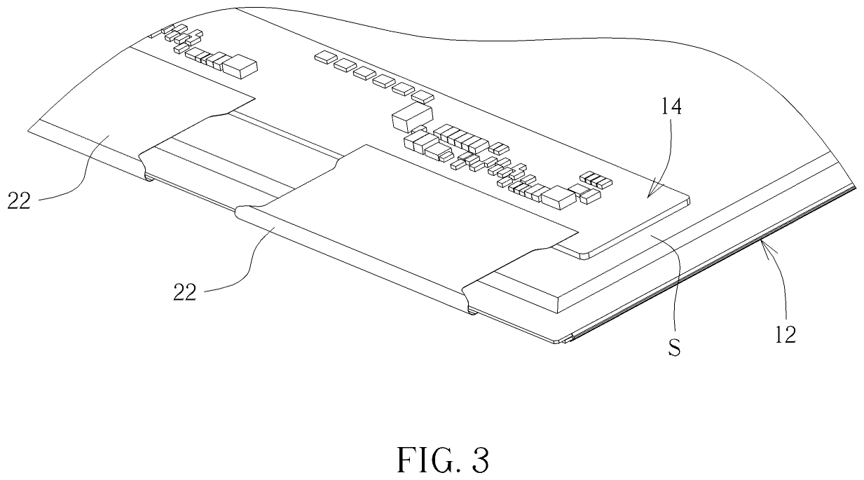

Please refer to FIGS. 1, 2, and 3. FIG. 1 is a perspective view of an OLED display device 10 according to an embodiment of the present invention. FIG. 2 is a partial exploded view of the OLED display device 10 in FIG. 1. FIG. 3 is a back-side view of an OLED panel module 12 in FIG. 2. As shown in FIGS. 1, 2, and 3, the OLED display device 10 of the present invention includes the OLED panel module 12, a flexible circuit board 14, a back plate 16, a bracket 18, and a covering sheet 20. The flexible circuit board 14 could preferably adopt a COF (Chip On Film) process to achieve flexibility and bending capabilities, but not limited thereto. The flexible circuit board 14 is electrically connected to the OLED panel module 12, which is used to control image display of the OLED panel module 12. As shown in FIG. 3, the flexible circuit board 14 forms at least one folded board portion 22, which is bent backward from the OLED panel module 12. The number of folded board portions 22 depends on the number of circuits connected from the flexible circuit board 14 to the OLED panel module 12, and the bent folded board portions 22 are attached to a back surface S of the OLED panel module 12 for saving space occupied by the flexible circuit board 14 inside the OLED display device 10, thereby achieving a thin design of the OLED display device 10 with a slim bottom bezel. In some embodiments, the folded board portion 22 further includes a printed circuit board having at least one connector, such as a daughter board or driver board, which is disposed on the back surface S. When the OLED display device 10 is placed horizontally and faces up, the back plate 16 is disposed below the OLED panel module 12, and the bracket 18 is disposed between the OLED panel module 12 and the back plate 16, such that the OLED panel module 12, the bracket 18 and the back plate 16 are stacked. In an embodiment of the present invention, when the OLED display device 10 stands vertically, the flexible circuit board 14 is bent backward under the bottom of the OLED panel module 12 and attached to the back surface S of the OLED panel module 12. The back plate 16 has a bent portion at the bottom side of the OLED display device 10 to form a side wall B. The side wall B could be bent again to form at least one clamping slot portion 24. The number of clamping slot portions 24 depends on the assembly requirements of the OLED display device 10. For example, the number and the size of the clamping slot portions 24 can be adjusted according to the size of the OLED display panel and internal space of the OLED display device 10.

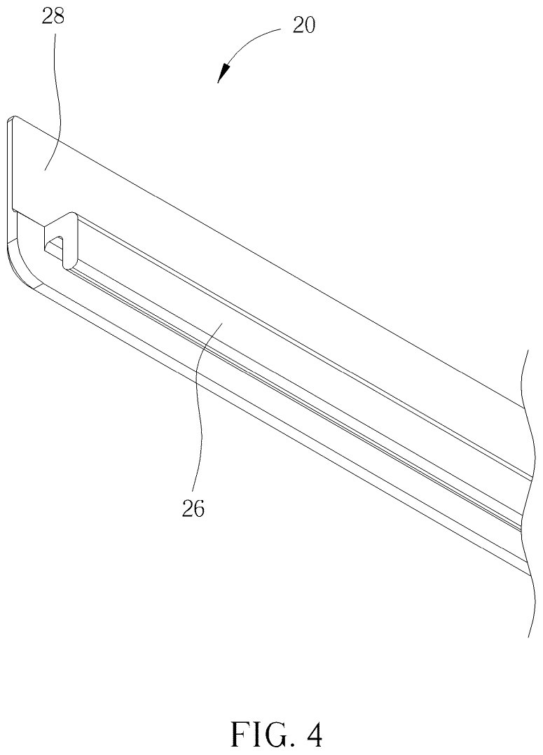

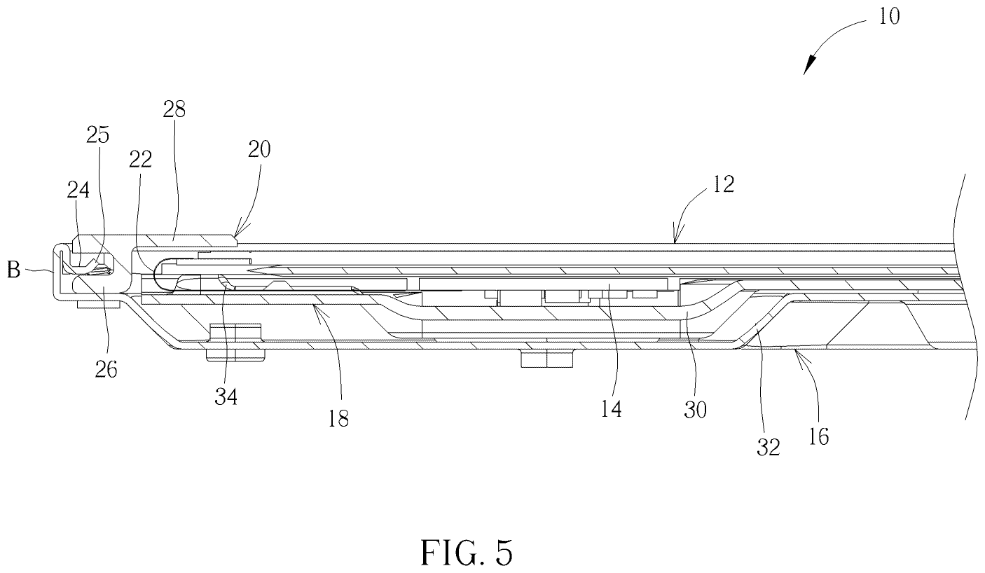

Please refer to FIGS. 1-5 for the structural relationship between the covering sheet 20 and the back plate 16. FIG. 4 is a back-side view of the covering sheet 20 in FIG. 2. FIG. 5 is a partial cross-sectional view of the OLED display device 10 along a cross-sectional line A-A in FIG. 1. In some embodiments of the present invention, the side wall B of the back plate 16 is folded inwardly by 180 degrees and then reversely folded to form the clamping slot portion 24. In this way, the clamping slot portion 24 and the back plate 16 are integrally formed in one piece, and a clamping slot space is formed between the clamping slot portion 24 and the main body of the back plate 16. The covering sheet 20 is preferably made of aluminum extrusion material to enhance the heat dissipation efficiency of the OLED display device 10, but not limited thereto. The covering sheet 20 covers the flexible circuit board 14 and the non-display area of the OLED panel module 12 and has a hook portion 26 and a covering portion 28, which are integrally formed in one piece. The hook portion 26 extends and bends from the covering portion 28. Accordingly, the hook portion 26 of the covering sheet 20 can be inserted obliquely into the clamping slot space between the back plate 16 and the clamping slot portion 24, and then rotated to vertically enter into the clamping slot space, so as to fix the covering sheet 20 to the side wall B of the back plate 16 via the clamping slot portion 24. In addition, the covering portion 28 covers the folded board portion 22 (as shown in FIG. 5), thereby preventing the folded board portion 22 and other internal components from being exposed.

In an embodiment of the present invention, the clamping slot portion 24 extends about 1.3 mm from the inwardly folded portion of the side wall B, which is parallel to the main body of the back plate 16, and then the clamping slot portion 24 folds and inclines outwardly to extend about 1.1 mm, which forms a guiding portion 25 of the clamping slot portion 24. The clamping slot portion 24 is disposed on both left and right sides or other positions of the side wall B horizontally, with a width of about 8 mm. Thus, the clamping slot space is formed internally with an opening about 1.6 mm and a depth about 3.2 mm. The covering sheet 20 is formed with a groove between the hook portion 26 and the covering portion 28, which has an opening of about 1.8 mm and a depth of about 3.4 mm. When the hook portion 26 is inserted into the clamping slot space, the guiding portion 25 of the clamping slot portion 24 also enters into the opening of the groove between the hook portion 26 and the covering portion 28 simultaneously, guiding the hook portion 26 to be rotated and inserted deeply into the clamping slot space. The aforesaid dimensions are only provided as examples, but the present invention is not limited thereto. In an embodiment of the present invention, a folded angle of the guiding portion 25 inclined outwardly is about 45 degrees, but not limited thereto. In an embodiment of the present invention, a vertical length of the covering portion 28 of the covering sheet 20 is about 13.6 mm, which could cover an internal space with length of about 8.7 mm and keep a vertical distance of about 1.15 mm from a display area of the OLED panel module 12. The covering portion 28 only covers the structures of a non-display area, which is at the bottom of the OLED panel module 12, thereby not blocking the visible angle range of the display screen. The aforesaid dimensions are only provided as examples, but the present invention is not limited thereto. In summary, the thickness of the side wall of the OLED display device 10 according to the present invention can be reduced to less than 5 mm, and the height of the bezel structures at the bottom of the front surface of the OLED display device 10 can be reduced to about 15.6 mm, so as to meet the specification requirements for a large-size, ultra-thin and bezel-less display device.

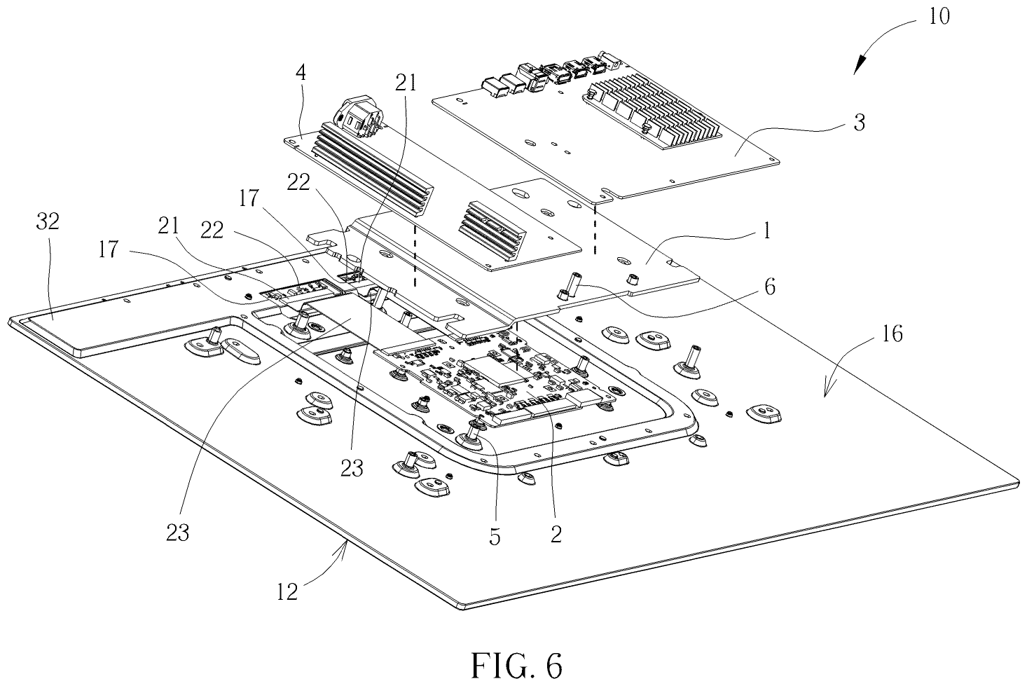

Furthermore, please refer to FIGS. 2, 3, and 6. FIG. 6 is an exploded view showing the back side of the OLED display device 10 in FIG. 1. In an embodiment of the present invention, the back plate and the bracket of the OLED display device 10 could have holes formed thereon, which allow the folded board portion to electrically connect to multi-layer circuit boards disposed on the back surface of the back plate. For example, at least one partition 1 and a plurality of layered circuit boards, such as a first circuit board 2 and second circuit boards 3, 4 in FIG. 6, can be disposed on the back side of the back plate 16. The first circuit board 2 is located inside or under the partition 1, while the second circuit boards 3, 4 are located outside or above the partition 1. The folded board portion 22 attached to the back surface S of the OLED panel module 12 is electrically connected to the first circuit board 2 disposed on the back surface of the back plate 16 under the partition 1, and the first circuit board 2 is electrically connected to the second circuit boards 3, 4 disposed above the partition 1. However, the present invention is not limited thereto. The number, arrangement, and connection of partition and layered circuit boards could be decided based on the practical requirements for the circuit configurations of the OLED display device 10. The back plate 16 and the bracket 18 form at least one aligned through hole, but the present invention is not limited thereto. The number of the holes can be decided based on the requirements for the electrical connections between the folded boards and the layered circuit boards. In this embodiment, the at least one aligned through hole could include two through holes 17, which are aligned with each other, respectively formed on the first recessed structure and the second recessed structure. The partition 1 is disposed on the back surface of the back plate 16 to form separated upper and lower spaces, accommodating the second circuit boards 3, 4 and the first circuit board 2, which are disposed on the back surface of the back plate 16 in a stacked manner. In some embodiments, the partition 1 could be made of a heat-dissipating metal material, such as aluminum extrusion material. The back surface of the back plate 16 could have a plurality of first support pillars 5 disposed thereon to keep the partition 1 a distance from the back plate 16, and the back plate 16 or the partition 1 could have a plurality of second support pillars 6 disposed thereon to keep the second circuit boards 3, 4 a distance from the partition 1, thereby forming a heat dissipation channel between the partition 1 and the first circuit board 2 and a heat dissipation channel between the partition 1 and the second circuit boards 3, 4. In some embodiments, the partition 1 is fixed onto the first support pillars 5 by screws and the second circuit boards 3, 4 are fixed onto the second support pillars 6 by screws, but not limited thereto. In some embodiments, the partition 1 together with the first circuit board 2 and the second circuit boards 3, 4 could be covered by a metal shielding case fixed to the back surface of the back plate 16 to block electromagnetic interference.

In some embodiments, the first circuit board 2 could be a display control circuit board, the second circuit board 3 could be a main circuit board, and the second circuit board 4 could be a power circuit board. However, the present invention is not limited thereto. For example, in another embodiment, some of the circuit boards could be replaced or partially replaced with an external image signal device or an external power transformer. Through the above design, as shown in FIG. 6, the folded board portion 22 can be electrically connected to the first circuit board 2 and the second circuit boards 3, 4 via at least one flat cable 23, which passes through the through holes 17 of the bracket 18 and the back plate 16. This configuration is used to control the display screen of the OLED panel module 12. The present invention could adopt other types of electrical connection cables or wires, such as braid wire or plural individual signal wires. The layered circuit board configuration of the present invention reduces the area occupied by a circuit board or non-layered circuit boards and also decreases the costs of maintenance or replacement when any layered circuit board fails.

In some embodiments, as shown in FIGS. 2 and 5, for preventing the folded board portion 22 attached to the back surface S from colliding with other internal components, which could result in damage or short-circuit of circuit components, the bracket 18 has a first recessed structure 30 corresponding to a position on the back surface S where the folded board portion 22 is attached to. The first recessed structure 30 covers the folded board portion 22 inside the bracket 18. Furthermore, the back plate 16 could have a second recessed structure 32 corresponding to the first recessed structure 30. The second recessed structure 32 covers the first recessed structure 30 and the folded board portion 22 inside the back plate 16. As shown in FIGS. 5 and 6, both the first recessed structure 30 of the bracket 18 and the second recessed structure 32 of the back plate 16 have the through holes 17 formed thereon. The connector 21 of the folded board portion 22 is located within the through hole 17, allowing the flat cable 23 to pass through the through hole 17 and electrically connect the folded board portion 22 without rubbing or colliding with the folded board portion 22.

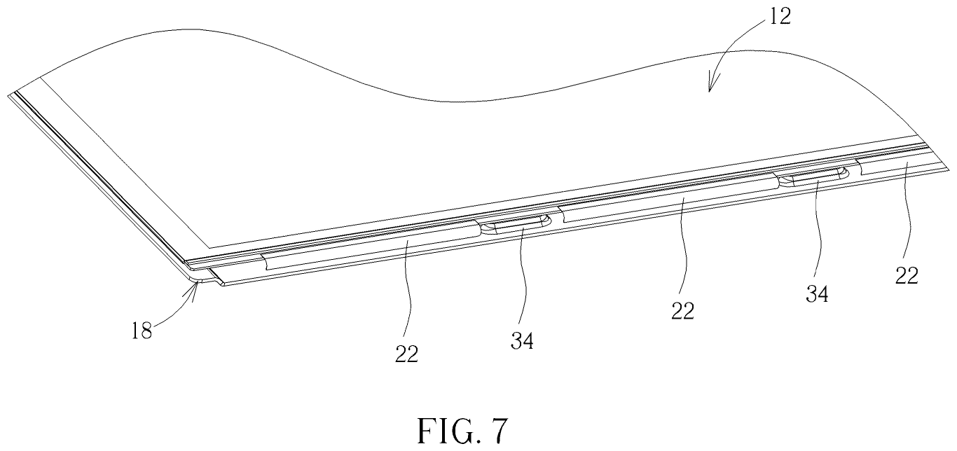

In addition, please refer to FIG. 7, which is a partial enlarged diagram of the OLED panel module 12 mounted on the bracket 18. In some embodiments, the bracket 18 could have at least one protruding structure 34 between the folded board portions 22 of the flexible circuit board 14. For example, there are two protruding structures 34 and three folded board portions 22 as shown in FIG. 7, but the present invention is not limited thereto. The number and position of protruding structures 34 depend on the configuration of the folded board portions 22 of the flexible circuit board 14. The protruding structure 34 can support the OLED panel module 12, so as to prevent the OLED panel module 12 from sliding down and pressing on the flexible circuit board 14, which may make the folded board portion 22 be compressed and fractured, or make the OLED panel module 12 collide with circuit components and cause damage or short circuit.

As demonstrated above, in some embodiments of the present invention, the assembly process of the OLED display device 10 includes the following steps. Firstly, the flexible circuit board 14 is folded and attached to the back surface S of the OLED panel module 12 to form the folded board portion 22. Next, the bracket 18 facing upwards is fixed to a front surface of the back plate 16, wherein the second recessed structure 32 of the back plate 16 covers or envelops the first recessed structure 30 of the bracket 18, the through hole 17 of the second recessed structure 32 is aligned with the through hole 17 of the first recessed structure 30, and the bracket 18 is fixed to the back plate 16 by adhesive bonding, structural engagement, screw fastening, or other fixing methods. Subsequently, the OLED panel module 12 with the folded board portion 22 is fixed onto the bracket 18, for example, by adhesive bonding, structural engagement, screw fastening, or other fixing methods, wherein the connector 21 of the folded board portion 22 is located within the through holes 17 of the bracket 18 and the back plate 16, and the side of the OLED panel module 12 connecting the flexible circuit board 14 is supported by the protruding structure 34 of the bracket 18. Afterwards, the covering sheet 20 is inserted into the clamping slot portion 24 of the back plate 16 and rotated to be engaged with the clamping slot portion 24, such that the covering sheet 20 is fixed at the bottom position of the front side of the back plate 16 and the covering portion 28 covers the flexible circuit board 14 of the OLED panel module 12. Then, the OLED display device 10 is flipped over with the back side facing upwards, and the first circuit board 2 is fixed to the back surface of the back plate 16. At least one flat cable 23 is inserted through the through holes 17 to connect the first circuit board 2 and the connector 21 of the folded board portion 22 for electrical connection. The partition 1 is locked onto the back surface of the back plate 16 and covers the first circuit board 2. The second circuit boards 3, 4 are fixed onto the partition 1, and the first circuit board 2 and the second circuit boards 3, 4 are electrically connected with wires. Finally, a shielding case and a rear cover are locked onto the back plate 16, wherein the shielding case covers the partition 1, the first circuit board 2, and the second circuit boards 3, 4, and the rear cover covers the shielding case and the back plate 16. The connectors on the second circuit boards 3, 4 are aligned with connector holes of the rear cover. In such a manner, the assembly of the OLED display device 10 is completed. In some embodiments of the present invention, the first circuit board 2 and the second circuit boards 3, 4 are not limited to being fixed by screw fastening, which means the first circuit board 2 and the second circuit boards 3, 4 could be secured by structural engagement, adhesives, or other fixing means. Furthermore, in some embodiments, the first circuit board 2 could be fixed to the partition 1 rather than on the back plate 16. The electrical connections are also not limited to be achieved by the aforesaid flat cables. Other electrical connection wires can be used as substitutes.

In some embodiments, the bracket 18 could be selectively omitted in the OLED display device 10 for further simplifying the structural design of the OLED display device 10. For example, the OLED display device 10 could only utilize the back plate 16 to accommodate the OLED panel module 12. The protruding structures 34 could be located on the back plate 16 and support the OLED panel module 12, and the back plate 16 or the back surface S of the OLED panel module 12 has a support structure formed thereon for supporting and separating the OLED panel module 12 from the back plate 16, so as to prevent the folded board portion 22 attached to the back surface S from contacting or colliding with the back plate 16. As mentioned above, the back plate 16 has the clamping slot portion 24, which allows the hook portion 26 of the covering sheet 20 to be inserted into and rotated to be engaged with the clamping slot portion 24. Furthermore, the clamping slot portion 24 extends to form the guiding portion 25, and the covering sheet 20 adjoins the side wall B of the back plate 16 once the covering sheet 20 is fixed. The clamping slot portion 24 and the covering sheet 20 may have same dimensions of structural portions as above-mentioned embodiments. Similarly, the first recessed structure 30 protrudes outward from the back plate 16 for accommodating the folded board portion 22 attached to the back surface S and the first recessed structure 30 has the through hole 17. The detailed descriptions of other related designs could be reasoned by analogy according to aforesaid embodiments.

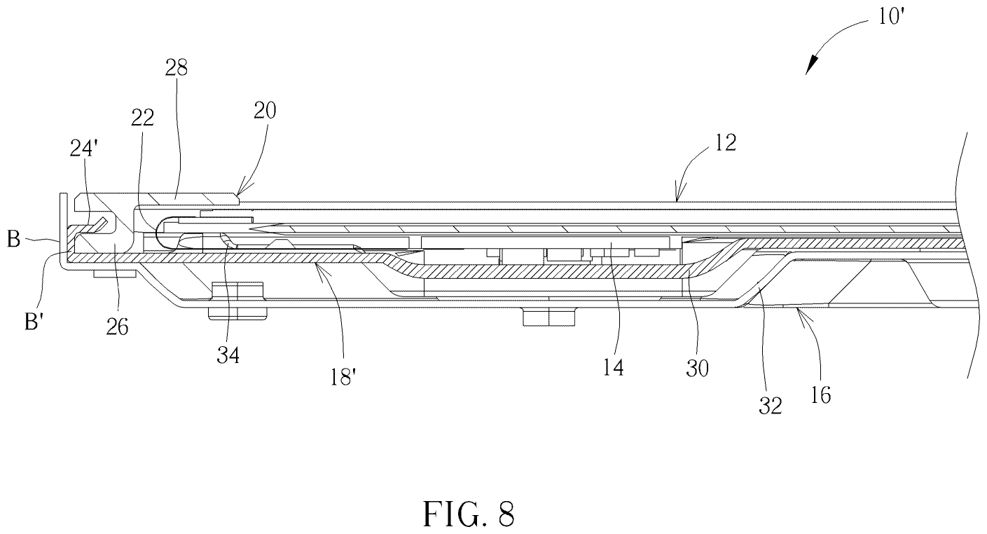

It should be noted that the clamping slot portion of the present invention is not limited to be integrally formed by repeatedly bending the side wall B of the backboard 16 as mentioned in the aforesaid embodiments. In some embodiments, the present invention could adopt the design that the clamping slot portion could be formed on the bracket by extending and repeatedly bending the bottom side wall of the bracket, which in turn forms the clamping slot portion to secure the covering sheet. Please refer to FIG. 8, which is a partial cross-sectional diagram of an OLED display device 10′ according to one embodiment of the present invention. Components with the same reference numbers as those in aforesaid figures represent components in similar structures or functions, and the related descriptions could be reasoned by analogy according to the aforesaid embodiments and are not repeated herein. As shown in FIG. 8, the OLED display device 10′ includes the OLED panel module 12, the flexible circuit board 14, the back plate 16, a bracket 18′, and the covering sheet 20. The bracket 18′ extends to a side of the back plate 16, such as the bottom side, for forming a side wall B′ inside the side wall B. The side wall B′ is bent to form at least one clamping slot portion 24′ for fixing the covering sheet 20. The number of clamping slot portions 24′ depends on the assembly requirements of the OLED display device 10′, for example, the number and size of clamping slot portions 24′ can be adjusted according to the panel size and internal space of the OLED display device 10′. In some embodiments, the bracket 18′ only partially extends to the side of the back plate 16, for example, the bracket 18′ may only extend at left and right sides to form the clamping slot portions 24′. In some embodiments, more than just the two sides of the bracket 18′ extend to the side of the back plate 16, but the side walls B′ and clamping slot portions 24′ are only formed at the two sides of the bracket 18′, but not limited thereto.

In some embodiments, the clamping slot portion 24′ of the bracket 18′ has a guiding structure like the guiding portion 25 as shown in FIG. 5. The hook portion 26 of the covering sheet 20 can be inserted into the clamping slot portion 24′ along the guiding structure and turned vertically, so as to make the covering portion 28 cover the clamping slot portion 24′ and the folded board portion 22 of the flexible circuit board 14 and substantially adjoin the side wall B of the back plate 16. As mentioned above, the details of the related designs, including the clamping slot portion 24′ that extends to form the guiding portion inclined outwardly, and the sizes of the clamping slot portion 24′ and the covering sheet 20, as well as the recessed structure 30 having the through hole 17, that protrudes outwardly from the bracket 18′ for accommodating the folded board portion 22 attached on the back surface S of the OLED panel module 12, could be reasoned by analogy according to the aforesaid embodiments.

In summary, the present invention discloses structure of an OLED display device having the covering sheet instead of external covering case. During assembly of the OLED display device, the covering sheet is inserted into the clamping slot portion, which is bent from the bottom side wall of the back plate, so that the covering sheet can be firmly assembled on the back plate. The OLED display device of the present invention omits a middle frame required in the prior art for installing an external covering case. The clamping slot portion, the bottom side wall, and the back plate (or the bracket) are integrally formed in one piece according to the assembly of the present invention, thereby meeting the requirements for a ultra-thin OLED display device with a slim bottom bezel. Moreover, the process of assembling the covering sheet is simpler than the traditional alignment and fastening structural designs of prior arts, so as to avoid misalignment caused by manual positioning, which is beneficial for simplifying the assembly or service process of the OLED display device and reducing the production defect rate. Additionally, the OLED display device of the present invention has plural circuit boards arranged in multi-layers, which can reduce the area occupied by traditional single circuit board in prior arts, and the circuit boards are separated by a heat-dissipating partition to form heat dissipation channels therebetween. When any of the circuit board fails, the OLED display device can be repaired without replacing all circuit boards, so as to effectively reduce the service cost of the OLED display device.

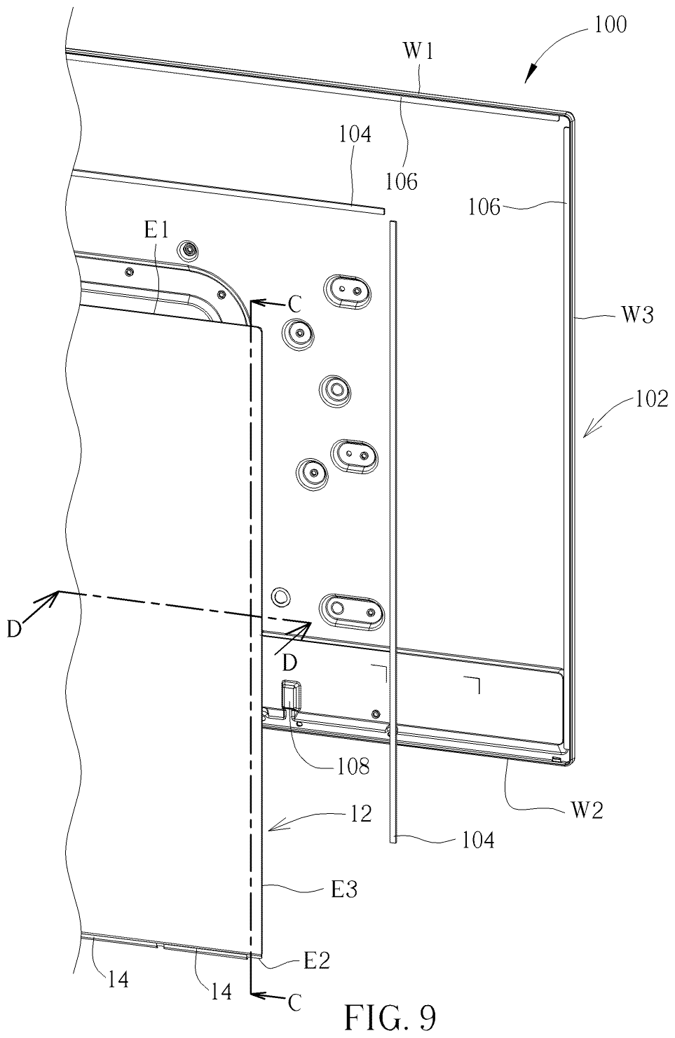

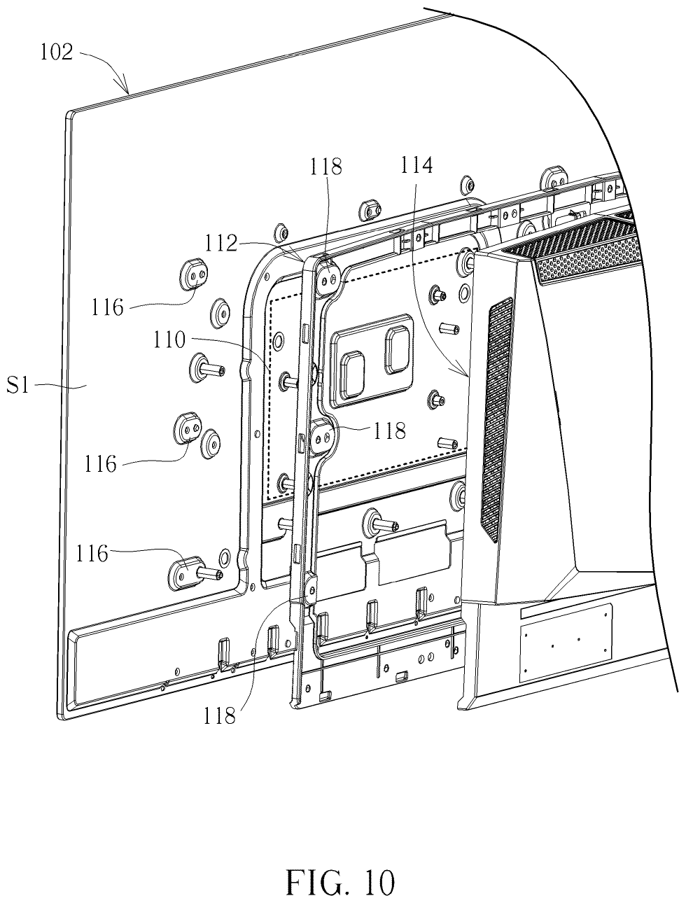

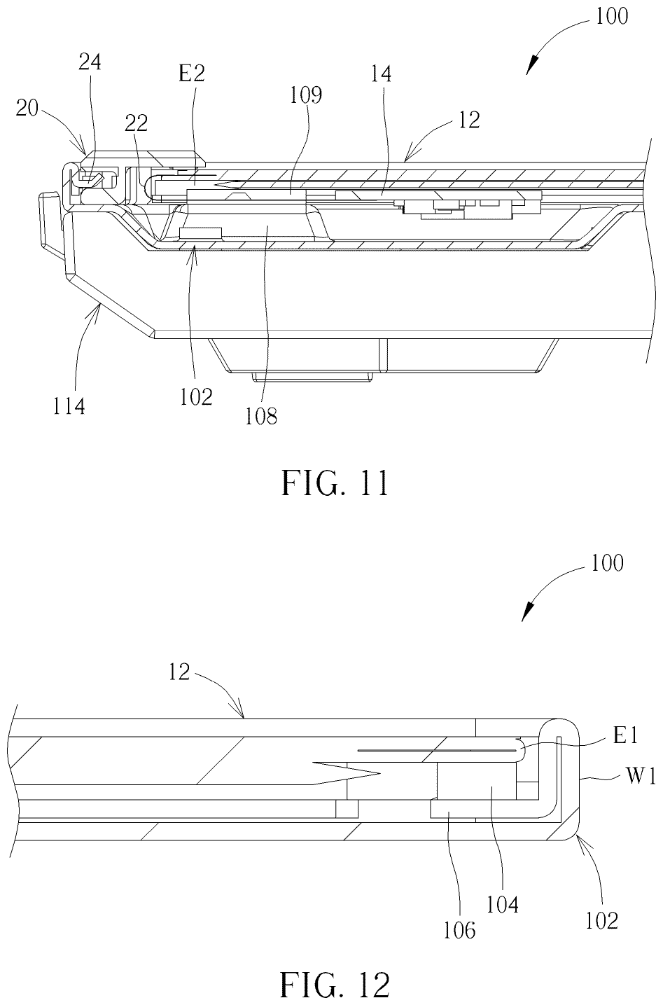

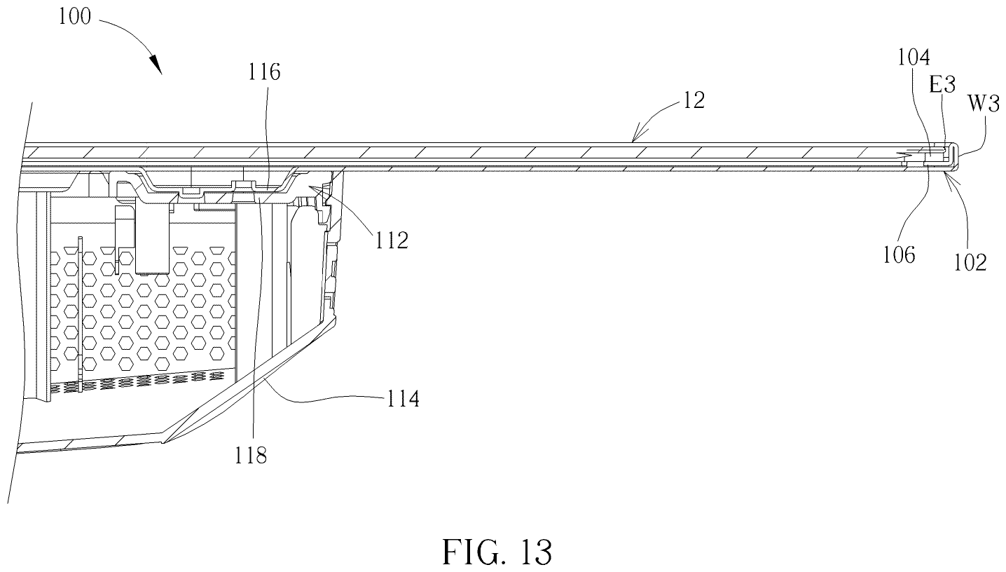

In some embodiments, the present invention could directly utilize the back plate to support the OLED panel module. For example, please refer to FIGS. 9-13. FIG. 9 is a partial exploded view of an OLED display device 100 according to another embodiment of the present invention. FIG. 10 is a partial exploded view of the OLED display device 100 in FIG. 9 from another viewing angle. FIG. 11 is a partial cross-sectional diagram of the OLED display device 100 in FIG. 9 along a cross-sectional line C-C after assembly. FIG. 12 is another partial cross-sectional diagram of the OLED display device 100 in FIG. 9 along the cross-sectional line C-C after assembly. FIG. 13 is a partial cross-sectional diagram of the OLED display device 100 in FIG. 9 along a cross-sectional line D-D after assembly. Components with the same reference numbers as those in aforesaid figures represent components in similar structures or functions, and the related descriptions could be reasoned by analogy according to the aforesaid embodiments and are not repeated herein.

As shown in FIGS. 9-13, the OLED display device 100 includes the OLED panel module 12, at least one flexible circuit board 14 (two shown in FIG. 9, but not limited thereto) electrically connected from a bottom E2 of the OLED panel module 12, a back plate 102, and at least two first adhesive tapes 104 (three first adhesive tapes 104 utilized in this embodiment for attaching to three sides of the OLED panel module 12, but not limited thereto). In an embodiment of the present invention, the back plate 102 extends to a top E1, the bottom E2, and two lateral sides E3 of the OLED panel module 12 to have a top wall W1, a bottom wall W2 and two side walls W3 respectively (only one lateral side E3 and only one side wall W3 are shown in FIG. 9, and the related description for the other lateral side E3 and the other side wall W3 could be reasoned by analogy according to the following description and omitted herein) for surrounding the OLED panel module 12 and the flexible circuit board 14. At least two support sheet portions 106 could be formed by extending and repeatedly bending at least two of the top wall W1, the bottom wall W2 and the two side walls W3. For example, in this embodiment, three support sheet portions 106 could be formed by extending and repeatedly bending the top wall W1 and the two side walls W3 respectively for attaching to the top E1 and the two lateral sides E3 of the OLED panel module 12 via the three first adhesive tapes 104 (as shown in FIG. 12 and FIG. 13), so as to support the OLED panel module 12 cooperatively on the back plate 102. To be more specific, the top wall W1 and the side walls W3 of the back plate 102 are folded inwardly by 180 degrees and then reversely folded to form the support sheet portions 106. In this way, the support sheet portions 106 and the back plate 102 are integrally formed in one piece for supporting the OLED panel module 12.

In an embodiment of the present invention, the support sheet portions 106 extend about 4.6 mm from the inwardly folded portions (could be regarded as a bezel of the OLED display device 100) of the top wall W1 and the two side walls W3 respectively, which are parallel to the main body of the back plate 16, and a stacked thickness of the back plate 102 with each support sheet portion 106 is equal to 1.2 mm, so as to make the OLED panel module 12 sunken to a depth of 0.8 mm relative to the top wall W1 and the two side walls W3 of the back plate 102. In summary, each wall thickness of the OLED display device 100 according to the present invention can be reduced to 4 mm, and a width of the bezel could be reduced to 1.2 mm, so as to meet the specification requirements for a large-size, ultra-thin and narrow-bezel display device. The aforesaid sizes are only provided as examples, but the present invention is not limited thereto.

In practical applications, the back plate 102 could have at least one protruding structure 108 (one shown in FIG. 9, but not limited thereto, meaning that the number of protruding structures 108 depends on the assembly requirements of the OLED display device 100) corresponding to the bottom E2 of the OLED panel module 12, and the OLED display device 100 could further include a second adhesive tape 109 corresponding to the protruding structure 108. As shown in FIG. 9 and FIG. 11, the protruding structure 108 is misaligned with the flexible circuit board 14, and the second adhesive tape 109 is attached between the protruding structure 108 and the bottom E2 of the OLED panel module 12 for supporting the bottom E2 of the OLED panel module 12 cooperatively with the protruding structure 108. In such a manner, the three support sheet portions 106 and the protruding structure 108 could support the OLED panel module 12 cooperatively for further enhancing the support strength of the back plate 102. Furthermore, as shown in FIG. 11, the design that the covering sheet 20 is inserted into the clamping slot space between the back plate 16 and the clamping slot portion 24 for preventing the folded board portion 22 of the flexible circuit board 14 and other internal components from being exposed as mentioned in the aforesaid embodiments could be also applied to this embodiment to form a curved display device, and the related description could be reasoned by analogy according to the aforesaid embodiments and omitted herein.

Via the aforesaid design, the OLED display device of the present invention omits the inner metal plate required in the prior art and directly utilizes the back plate to support the OLED panel module. Thus, the present invention can efficiently solve the prior art problem that the inner metal plates and the adhesive tapes occupy internal space of the OLED display devices and require time-consuming and strenuous assembly steps during mass production, so as to simplify the assembly steps and reduce the manufacturing costs for the OLED display devices as well as meet the requirements for a ultra-thin OLED display device with a slim bezel.

It should be mentioned that the present invention could directly utilize at least one support sheet portion of the back plate to support the bottom of the OLED panel module. For example, in one embodiment that the protruding structure 108 is omitted, there could be one support sheet portion 106 (but not limited thereto) misaligned with the flexible circuit board 14 and formed by extending and repeatedly bending the bottom wall W2 of the back plate 102 for attaching to the bottom E2 of the OLED panel module 12 via an adhesive tape (e.g., the first adhesive tape 104), so as to support the OLED panel module 12 cooperatively with the aforesaid support sheet portions 106 formed on the top wall W1 and the side walls W3 of the back plate 102. As for more detailed description for the support sheet portion 106 formed on the bottom wall W2 of the back plate 102, it could be reasoned by analogy according to FIGS. 9 and 12 and omitted herein.

Furthermore, the present invention could further utilize a rear casing to cover the aforesaid circuit boards as shown in FIG. 6 for protection. For example, as shown in FIG. 10, the OLED display device 100 could further include at least one circuit board 110 (one shown by dashed lines in FIG. 10, but not limited thereto), a connection frame 112, and a rear casing 114. The circuit board 110 is disposed on a back surface S1 of the back plate 102 and could be a display control circuit board, a main circuit board, or a power circuit board, but the present invention is not limited thereto. For example, in another embodiment, the circuit board 110 could be replaced with an external image signal device or an external power transformer. The connection frame 112 is connected to the back surface S1 of the back plate 102 (by screws or structural engagement, but not limited thereto) and surrounds the circuit board 110. The rear casing 114 is connected to the connection frame 112 (by screws or structural engagement, but not limited thereto) to cover the circuit board 110 for protection. To be more specific, in this embodiment, the back plate 102 could recess toward the rear casing 114 to form at least one first positioning structure 116 (three shown in FIG. 10, but not limited thereto), and the connection frame 112 could form a second positioning structure 118 corresponding to the first positioning structure 116. As such, the second positioning structure 118 could receive the first positioning structure 116 (by screws or structural engagement, but not limited thereto) to precisely position the connection frame 112 on the back plate 102, so as to simplify the assembly process of fixing the rear casing 114 to the back plate 102 via the connection frame 112.

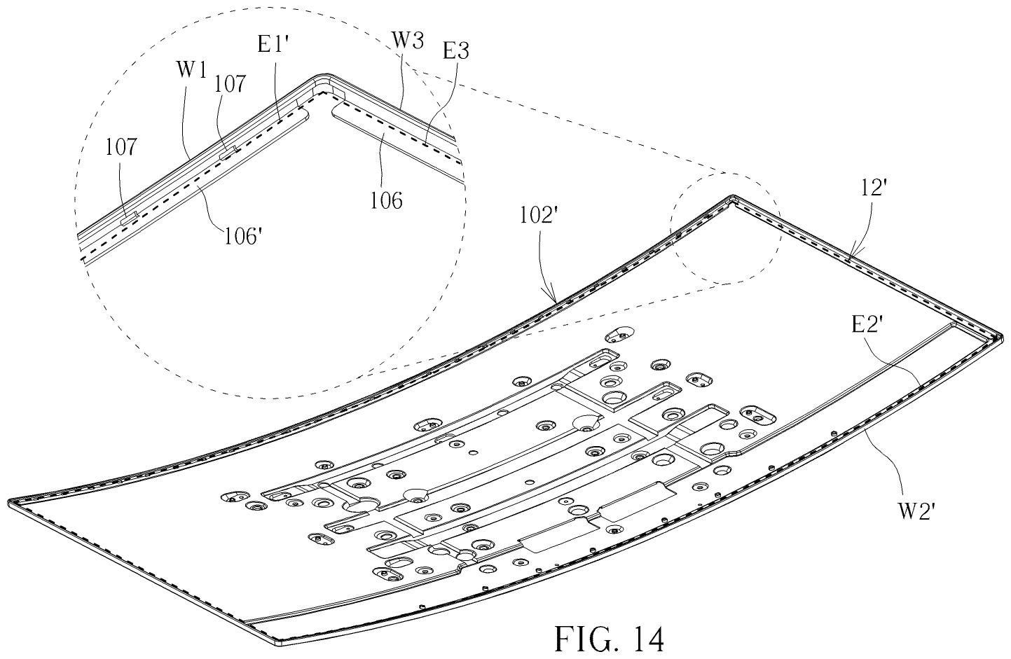

Moreover, the aforesaid back plate design could be applied to a curved display device. For example, please refer to FIG. 14, which is a partial enlarged diagram of a back plate 102′ supporting an OLED panel module 12′ according to another embodiment of the present invention. Components with the same reference numbers as those in aforesaid figures represent components in similar structures or functions, and the related descriptions could be reasoned by analogy according to the aforesaid embodiments and are not repeated herein. As shown in FIG. 14, the OLED panel module 12′ (shown by dashed lines in FIG. 14) could be a curved display panel, and a top E1′ and a bottom E2′ of the OLED panel module 12′ are curved and a top wall W1′ and a bottom wall W2′ of the back plate 102′ are curved along the top E1′ and the bottom E2′, respectively. A support sheet portion 106′ could be formed by extending and repeatedly bending the top wall W1′, and the two support sheet portions 106 could be formed by extending and repeatedly bending the two side walls W3 respectively. In such a manner, the support sheet portion 106′, the two support sheet portions 106 and the back plate 102′ are integrally formed in one piece for supporting the OLED panel module 12′. To be noted, the support sheet portion 106′ formed by extending and repeatedly bending the top wall W1′ has at least one hole 107 (two shown in FIG. 14, but not limited thereto). As shown in FIG. 14, the hole 107 could be preferably formed on a bent position of the support sheet portion 106′ to decrease the bending strength of the back plate 102′, so as to make the back plate 102′ bent at the top wall W1′ more smoothly for reducing the manufacturing cost for the back plate 102′. As for the other derived designs (e.g., the protruding structure design and the positioning structure design) for the back plate 102′, the related description could be reasoned by analogy according to the aforesaid embodiments and omitted herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light emitting diode (OLED) display device comprising:
an OLED panel module;
at least one flexible circuit board electrically connected from a bottom of the OLED panel module;
a back plate extending to a top, the bottom, and two lateral sides of the OLED panel module to have a top wall, a bottom wall and two side walls respectively for surrounding the OLED panel module and the at least one flexible circuit board, wherein at least two support sheet portions are formed by extending and repeatedly bending at least two of the top wall, the bottom wall and the two side walls; and
at least two first adhesive tapes attached between the at least two support sheet portions and the OLED panel module, for supporting the OLED panel module cooperatively with the at least two support sheet portions.

2. The OLED display device of claim 1, wherein the back plate has at least one protruding structure corresponding to the bottom of the OLED panel module, and the at least one protruding structure is misaligned with the at least one flexible circuit board and supports the bottom of the OLED panel module.

3. The OLED display device of claim 2, wherein the OLED display device further include a second adhesive tape corresponding to the at least one protruding structure, and the second adhesive tape is attached between the at least one protruding structure and the bottom of the OLED panel module for supporting the bottom of the OLED panel module cooperatively with the at least one protruding structure.

4. The OLED display device of claim 1, wherein a stacked thickness of the back plate with the support sheet portion is equal to 1.2 mm.

5. The OLED display device of claim 1, wherein the OLED display device further comprises:
at least one circuit board disposed on a back surface of the back plate;
a connection frame connected to the back surface of the back plate and surrounding the at least one circuit board; and
a rear casing connected to the connection frame for covering the at least one circuit board.

6. The OLED display device of claim 5, wherein the back plate recesses toward the rear casing to form at least one first positioning structure, the connection frame forms a second positioning structure corresponding to the at least one first positioning structure, and the second positioning structure receives the at least one first positioning structure to position the connection frame on the back plate.

7. An OLED display device comprises:
an OLED panel module having a display area and a non-display area located on a front surface of the OLED panel module;
a flexible circuit board electrically connected and bent backward from a bottom of the OLED panel module to form at least one folded board portion attached to a back surface of the OLED panel module;
a back plate extending to a top, the bottom, and two lateral sides of the OLED panel module to have a top wall, a bottom wall and two side walls respectively for surrounding the OLED panel module and the flexible circuit board, wherein at least two support sheet portions are formed by extending and repeatedly bending at least two of the top wall, the bottom wall and the two side walls;
wherein the bottom wall covers the OLED panel module and the flexible circuit board at the bottom, at least one clamping slot portion is formed by extending and repeatedly bending at least one portion of the bottom wall, at least one clamping slot space is formed between the at least one clamping slot portion and the back plate, and the back plate, the bottom wall and the at least one clamping slot portion are formed integrally in one piece; and
a covering sheet covering the flexible circuit board and the non-display area, the covering sheet having at least one hook portion and a covering portion, the at least one hook portion extending and bending from the covering portion, wherein the at least one hook portion is inserted into the at least one clamping slot space such that the clamping slot portion is between the at least one hook portion and the covering portion.

8. The OLED display device of claim 7, wherein the back plate has at least one protruding structure corresponding to the bottom of the OLED panel module, and the at least one protruding structure is misaligned with the at least one folded board portion and supports the bottom of the OLED panel module.

9. The OLED display device of claim 8, wherein the OLED display device further include a second adhesive tape corresponding to the at least one protruding structure, and the second adhesive tape is attached between the at least one protruding structure and the bottom of the OLED panel module for supporting the bottom of the OLED panel module cooperatively with the at least one protruding structure.

10. The OLED display device of claim 7, wherein a stacked thickness of the back plate with the support sheet portion is equal to 1.2 mm.

11. The OLED display device of claim 7, wherein the OLED display device further comprises:
at least one circuit board connected to the at least one folded board portion and disposed on a back surface of the back plate;
a connection frame connected to the back surface of the back plate and surrounding the at least one circuit board; and
a rear casing connected to the connection frame for covering the at least one circuit board.

12. The OLED display device of claim 11, wherein the back plate recesses toward the rear casing to form at least one first positioning structure, the connection frame forms a second positioning structure corresponding to the at least one first positioning structure, and the second positioning structure receives the at least one first positioning structure to position the connection frame on the back plate.

13. The OLED display device of claim 7, wherein the top and the bottom of the OLED panel module are curved, and the top wall and the bottom wall of the back plate are curved along the top and the bottom, respectively.

14. The OLED display device of claim 13, wherein the support sheet portion formed by extending and repeatedly bending the top wall has at least one hole, and the at least one hole is formed on a bent position of the support sheet portion.

15. A curved display device comprises:
a curved OLED panel module;
at least one flexible circuit board electrically connected from a bottom of the curved OLED panel module;
a back plate extending to a top, the bottom, and two lateral sides of the curved OLED panel module to have a top wall, a bottom wall and two side walls respectively for surrounding the curved OLED panel module and the at least one flexible circuit board, wherein the top wall and the bottom wall of the back plate are curved along the top and the bottom of the curved OLED panel module respectively, and at least two support sheet portions are formed by extending and repeatedly bending at least two of the top wall, the bottom wall and the two side walls; and
at least two first adhesive tapes attached between the at least two support sheet portions and the curved OLED panel module, for supporting the curved OLED panel module cooperatively with the at least two support sheet portions.

16. The curved OLED display device of claim 15, wherein the back plate has at least one protruding structure corresponding to the bottom of the curved OLED panel module, and the at least one protruding structure is misaligned with the at least one flexible circuit board and supports the bottom of the curved OLED panel module.

17. The curved OLED display device of claim 16, wherein the curved OLED display device further include a second adhesive tape corresponding to the at least one protruding structure, and the second adhesive tape is attached between the at least one protruding structure and the bottom of the curved OLED panel module for supporting the bottom of the curved OLED panel module cooperatively with the at least one protruding structure.

18. The curved OLED display device of claim 15, wherein the curved OLED display device further comprises:
at least one circuit board disposed on a back surface of the back plate;
a connection frame connected to the back surface of the back plate and surrounding the at least one circuit board; and
a rear casing connected to the connection frame for covering the at least one circuit board.

19. The curved OLED display device of claim 18, wherein the back plate recesses toward the rear casing to form at least one first positioning structure, the connection frame forms a second positioning structure corresponding to the at least one first positioning structure, and the second positioning structure receives the at least one first positioning structure to position the connection frame on the back plate.

20. The OLED display device of claim 15, wherein the support sheet portion formed by extending and repeatedly bending the top wall has at least one hole, and the at least one hole is formed on a bent position of the support sheet portion.
